(19) United States
(12) Patent Application Publication
(10) Pub. No.: US 2026/0360431 A1
(43) Pub. Date: Nov. 12, 2026

(54) MEMORY DEVICE AND PROGRAMMING METHOD THEREOF

(71) Applicant: MACRONIX International Co., Ltd., Hsinchu (TW)

(72) Inventors: You-Liang Chou, Taichung City (TW); Wen-Che Tsai, Hualien City (TW)

(73) Assignee: MACRONIX International Co., Ltd., Hsinchu (TW)

(21) Appl. No.: 19/200,680

(22) Filed: May 7, 2025

(51) Int. Cl. G11C 16/10; G11C 16/04; G11C 16/08; G11C 16/24

(52) U.S. Cl. CPC G11C 16/102; G11C 16/0483; G11C 16/08; G11C 16/24

(57) ABSTRACT

A memory device and a programming method thereof are provided. The memory device is, for example a three dimensional NAND flash memory circuit, and provides a storage media with high-performance and high-capacity. The programming method includes: selecting a plurality of first memory cell strings to be select memory stings, and selecting a plurality of second memory cell strings to be de-select memory stings; in a first phase, respectively turning on a plurality of memory cell string selection switches of the selected memory strings, applying a discharge voltage on bit lines of the selected memory strings; in a second phase, applying a select voltage on the bit lines of the selected memory strings, and applying an inhibit voltage on bit lines of the de-selected memory strings; and in a third phase, applying a program voltage on a word line corresponding to a selected memory cell of the selected memory strings.

### BACKGROUND

### Technical Field

The disclosure relates to a memory device and a programming method thereof, and in particular relates to a memory device capable of improving the performance of programming operations and a programming method thereof.

### Description of Related Art

To enhance the storage density of memory devices, three-dimensional multi-cell string NAND flash memory devices have been proposed. Such memory devices comprise a plurality of memory cell strings. When performing programming operations on selected memory cells, due to the high-density configuration relationship of a plurality of memory strings, the programming operations conducted on the selected memory cells frequently affect adjacent de-selected memory cells. Therefore, how to improve the programming performance of the selected memory cells and effectively inhibit the de-selected memory cells to prevent them from being affected by the programming operation is an important topic for those skilled in the art.

### SUMMARY

A memory device and a programming method thereof, which may improve the performance of programming operations, are provided in the disclosure.

The programming method of the memory device of the disclosure includes the following operation. A plurality of first memory cell strings are selected to be a plurality of selected memory strings, and a plurality of second memory cell strings are selected to be a plurality of de-selected memory strings. In a first phase, a plurality of memory cell string selection switches of the selected memory string are respectively turned on, and a discharge voltage is applied on a plurality of bit lines of the selected memory strings. In a second phase, a select voltage is applied on the bit lines of the selected memory strings, and an inhibit voltage is applied on bit lines of the de-selected memory strings. In a third phase, a program voltage is provided on a word line corresponding to a plurality of selected memory cells of the selected memory strings.

The memory device of the disclosure includes a plurality of memory cell strings and a controller. In the programming operation, the memory cell strings are divided into a plurality of selected memory strings and a plurality of de-selected memory strings. The controller is coupled to the memory cell strings to execute the above-mentioned programming operations.

Based on the above, the programming operation of the memory device of the disclosure, in the first phase, is accomplished by respectively turning on a plurality of memory cell string selection switches on the selected memory strings and applying a discharge voltage on the bit lines. In this way, through the bit line coupling effect, a channel of the selected memory string may perform a discharge operation according to the discharge voltage on the bit line. Thus, before the programming operation, the voltage of the channel of the selected memory string may be effectively reduced to a relatively low voltage value, which may effectively improve the working performance of the subsequent programming operation.

### BRIEF DESCRIPTION OF THE DRAWINGS

FIG. 1 is a schematic diagram of a memory device of an embodiment of the disclosure.

FIG. 2 is a schematic diagram of an implementation of a memory cell string of an embodiment of the disclosure.

FIG. 3 is a waveform diagram of a programming operation of a memory device of an embodiment of the disclosure.

FIG. 4 is a flowchart of a programming operation of a memory device of an embodiment of the disclosure.

### DETAILED DESCRIPTION OF DISCLOSED EMBODIMENTS

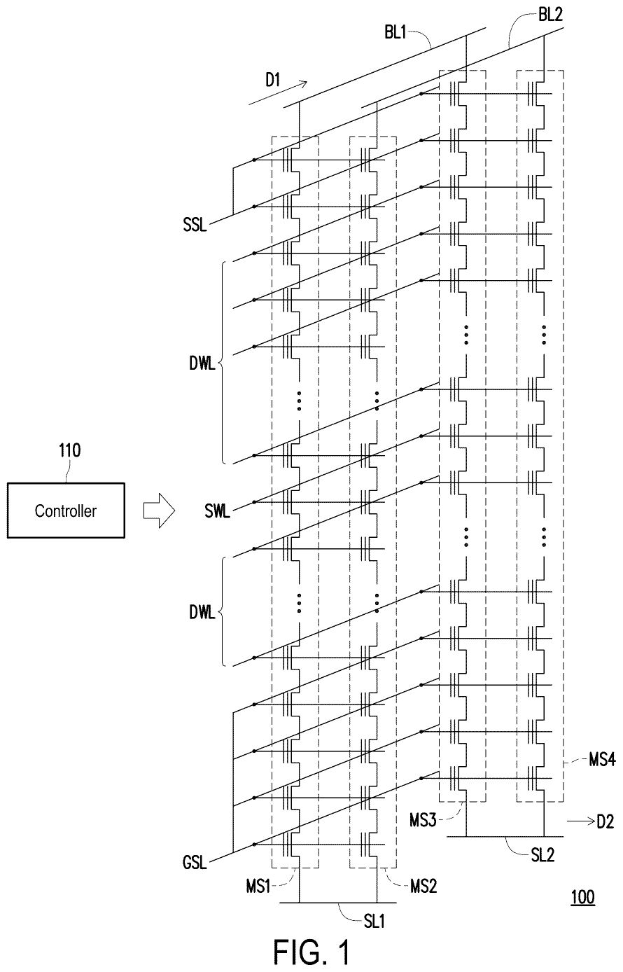

Referring to FIG. 1, FIG. 1 is a schematic diagram of a memory device of an embodiment of the disclosure. A memory device 100 includes a plurality of memory cell strings MS1 to MS4 and a controller 110. The memory cell strings MS1 to MS4 are configured in a three-dimensional stacking manner. The memory cell strings MS1 and MS3 are disposed along a direction D1. The memory cell strings MS2 and MS4 are disposed along the direction D1. The memory cell strings MS1 and MS2 are disposed along a direction D2. The memory cell strings MS3 and MS4 are disposed along the direction D2. The memory cell strings MS1 and MS3 are commonly coupled to a bit line BL1 which is also disposed along the direction D1. The memory cell strings MS2 and MS4 are commonly coupled to the bit line BL2 which is also disposed along the direction D1. On the other hand, the memory cell strings MS1 and MS2 are commonly coupled to a source line SL1 which is also disposed along the direction D2. The memory cell strings MS3 and MS4 are commonly coupled to a source line SL2 which is also disposed along the direction D2.

In this embodiment, each memory cell string MS1 to MS4 has a plurality of memory cells and switches. The memory cell string selection switches in each of the memory cell strings MS1 to MS4 commonly receive a memory cell string selection signal SSL. The ground selection switch in each of the memory cell strings MS1 to MS4 receives a ground selection signal GSL. The memory cells in the memory cell strings MS1 to MS4 correspond to each other and respectively receive a plurality of word line signals. Corresponding to a programming operation to be executed, a portion of the memory cell strings MS1 to MS4 (e.g., memory cell strings MS1 and MS2) may be set as selected memory strings, and another portion of the memory cell strings MS1 to MS4 (e.g., memory cell strings MS3 and MS4) may be set as de-selected memory strings. Under such conditions, the bit line BL1 may be a select bit line, and the bit line BL2 may be a de-select bit line. Correspondingly, the source line SL1 may be a select source line, and the source line SL2 may be a de-select source line.

It is worth noting that only four memory cell strings MS1 to MS4 are provided in the memory device 100 of this embodiment as examples for illustration. In fact, the memory device 100 may have one or more groups of memory cell strings MS1 to MS4 as shown in FIG. 1, and there is no specific limit on the number.

The controller 120 is coupled to the memory cell strings MS1 to MS4. The controller 120 is configured to control the programming operations of the memory cell strings MS1 to MS4. For details of the operation of the controller 120, please refer to the description of the following embodiments.

In this embodiment, the controller 120 may be a processor with computing capabilities. Alternatively, the controller 120 may be a hardware circuit designed through a hardware description language (HDL) or any other digital circuit design method known to those with ordinary knowledge in the art, and implemented through a field programmable logic gate array (FPGA), a complex programmable logic device (CPLD), or an application-specific integrated circuit (ASIC), without any specific limitations.

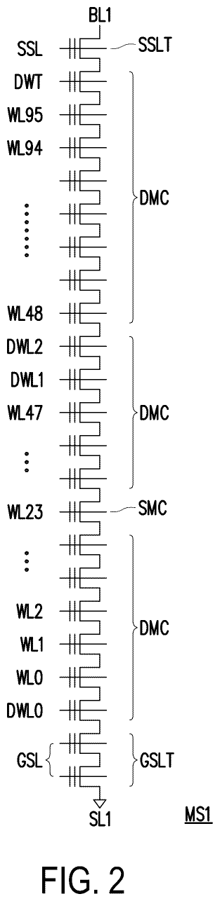

Referring to FIG. 2, FIG. 2 is a schematic diagram of an implementation of a memory cell string of an embodiment of the disclosure. Taking the memory cell string MS1 of FIG. 1 as an example, the memory cell string MS1 includes a plurality of transistors connected in series between a bit line BL1 and a source line SL1. In the memory cell string MS1, the memory cell string selection switch SSLT is coupled to the bit line BL1, the ground selection switch GSLT is coupled to the source line SL1, and the plurality of memory cells are coupled between the memory cell string selection switch SSLT and the ground selection switch GSLT. In this embodiment, the plurality of memory cells respectively sequentially (from top to bottom in the figure) receive the control signal DMT, word line signals WL95 to WL48, dummy word line signals DWL2 and DWL1, word line signals WL47 to WL0, and dummy word line signal DWL0. When executing a programming operation, a memory cell in the memory cell string MS1 may be set as a selected memory cell SMC to execute the programming operation, and the remaining memory cells may be de-selected memory cells DMC.

In this embodiment, the memory cell string MS1 may be a memory cell string of a NAND flash memory.

Of course, the memory cell string MS1 in FIG. 2 is merely an example for illustration and is not intended to limit the scope of implementation of the disclosure. In practical applications, any memory cell string commonly known to those skilled in the art may be applied to the disclosure without any specific limitation.

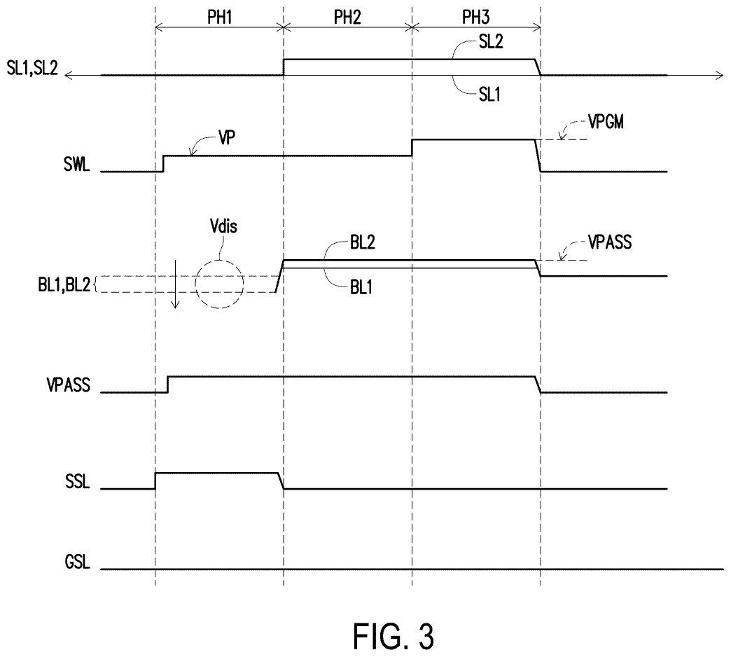

For details of the programming operation of the embodiment of the disclosure, please refer to FIG. 1 and FIG. 3, wherein FIG. 3 is a waveform diagram of a programming operation of a memory device of an embodiment of the disclosure. The memory cell string MS1 is taken as a selected memory string, and the memory cell strings MS2 to MS4 are taken as de-selected memory strings as an example. In the first phase PH1 of the programming operation, the source line SL1 coupled to the memory cell strings MS1 and MS2 is a select source line, and the source line SL2 coupled to the memory cell strings MS3 and MS4 is a de-select source line. At this time, the source lines SL1 and SL2 are both maintained at a low voltage value such as a reference ground voltage. The select word line SWL corresponding to the selected memory cell to be programmed may be pre-pulled up to a voltage VP.

On the other hand, in a first phase PH1, the voltages of the bit lines BL1 and BL2 may be set to a discharge voltage Vdis. The discharge voltage Vdis is, for example, 0V or a negative voltage value lower than 0V. It is worth noting that, also in the first phase PH1, a voltage value of the memory cell string selection signal SSL may be pulled high, and the memory cell selection switches of the memory cell strings MS1 to MS4 may be turned on. Thus, the turned-on memory cell string selection switches may respectively couple channels of the memory cell strings MS1 to MS4 with the corresponding bit lines BL1 and BL2, and discharge the charges in the channels of the memory cell strings MS1 to MS4 to the bit lines BL1 and BL2 with relatively low voltage values through the memory cell string selection switches. Therefore, the first phase PH1 may be referred to as a channel discharge phase.

On the other hand, in the first phase PH1, the de-select word lines DWL corresponding to the de-selected memory cells may receive a pass voltage VPASS.

After the first phase PH1, in a second phase PH2, the source line SL1 as the select source line may be at a first voltage (e.g., equal to the reference ground voltage), and the source line SL2 as the de-select source line may be at a second voltage (e.g., equal to 8V). By receiving the source line SL2 of the second voltage which is relatively high, the memory cell strings MS3 and MS4 which are de-selected memory strings may be inhibited in the programming operation.

In addition, also in the second phase PH2, the voltage values of the bit lines BL1 and BL2 are synchronously pulled high, and a voltage value of the bit line BL1 as the select bit line may be lower than a voltage value of the bit line BL2 as the select bit line. In this embodiment, the voltage value of the bit line BL1 is, for example, 3 volts, and the voltage value of the bit line BL2 is, for example, 8 volts. By setting the voltage value of the bit line BL2 to 8 volts, the corresponding memory cell strings MS2 and MS4 as de-selected memory strings may be effectively inhibited.

On the other hand, in the second phase PH2, voltages on the select word line SWL and the de-select word lines DWL are maintained the same as those in the first phase PH1 without change. The voltage value of the memory cell string selection signal SSL may be pulled down, and the memory cell selection switches of the memory cell strings MS1 to MS4 may be turned off.

In this embodiment, the second phase PH2 is a gate-induced-drain-leakage (GIDL) boost phase.

In a third phase PH3 after the second phase PH2, the voltage on the select word line SWL is pulled up from the voltage VP to a program voltage VPGM, so as to perform a programming operation on the selected memory cell in the selected memory string MS1. In the third phase PH3, the voltage values of the memory cell string selection signal SSL, the bit lines BL1 and BL2, the source lines SL1 and SL2, and the de-select word line DWL are maintained the same as the voltage values in the second phase PH2 without change. In this embodiment, the third phase PH3 is a programming phase.

In the first phase PH1 to the third phase PH3, the ground selection signal GSL is maintained at the reference ground voltage.

After the third phase PH3, when the programming operation is completed, the voltage values of all signals may be pulled down to the reference ground voltage.

In this embodiment, the memory device turns on the memory cell string selection switches of the memory cell strings MS1 to MS4 in the first phase PH1, and enables the channels of the memory cell strings MS1 to MS4 to be directly coupled to the bit lines BL1 and BL2. By pulling down the voltage values of the bit lines BL1 and BL2 to 0 volts or a negative voltage, the channels of the memory cell strings MS1 to MS4 may perform effective discharge operations in the first phase PH1 to effectively pull down the voltage values of the channels of the memory cell strings MS1 to MS4. As a result, in the programming operation performed in the third phase PH3, there may be a sufficient voltage difference between the program voltage VPGM and the voltage of the channel of the memory cell string MS1, which may effectively improve the performance of the programming operation.

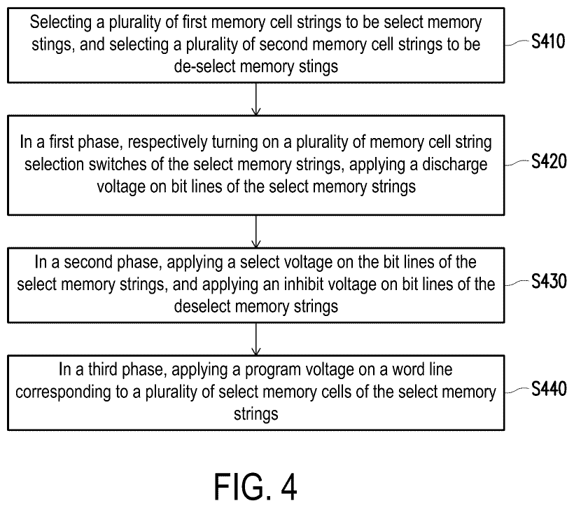

Referring to FIG. 4, FIG. 4 is a flowchart of a programming operation of a memory device of an embodiment of the disclosure. In step S410, the controller of the memory device may select a plurality of first memory cell strings to be a plurality of selected memory strings. The controller of the memory device may further select a plurality of second memory cell strings to be a plurality of de-selected memory strings. In step S420, in the first phase, the controller of the memory device may respectively turn on a plurality of memory cell string selection switches of the selected memory strings and apply a discharge voltage on a plurality of bit lines of the selected memory strings. In step S430, in the second phase, the controller of the memory device may apply a select voltage on the bit lines of the selected memory strings and an inhibit voltage may be applied on the bit lines of the de-selected memory strings. In step S440, in the third phase, the controller of the memory device may provide a program voltage to a word line corresponding to the selected memory cells of the selected memory strings.

The implementation details of the above steps have been described in detail in the foregoing embodiment, and are not repeated herein.

To sum up, during the first phase of the programming operation in this disclosure, the memory cell string selection switches on the memory cell strings are respectively turned on, and a discharge voltage is applied on a plurality of bit lines of the memory cell strings. In this way, the channel in the memory cell string may be discharged through the mechanism of bit line coupling, so that a sufficiently large voltage difference may be generated when the program voltage is applied to the selected memory cell. By effectively discharging the channels in the memory cell string, the voltage value of the program voltage may be reduced, the power consumption required for the programming operation may be reduced, and the rate of the programming operation may be increased, thereby improving the performance of the programming operation.

What is claimed is:

1. A programming method of a memory device, comprising:
selecting a plurality of first memory cell strings to be a plurality of selected memory strings, selecting a plurality of second memory cell strings to be a plurality of de-selected memory strings;
respectively turning on a plurality of memory cell string selection switches of the selected memory string, applying a discharge voltage on a plurality of bit lines of the selected memory strings in a first phase;
applying a select voltage on the bit lines of the selected memory strings, applying an inhibit voltage on a plurality of bit lines of the de-selected memory strings in a second phase; and
providing a program voltage on a word line corresponding to a plurality of selected memory cells of the selected memory strings in a third phase.

2. The programming method according to claim 1, wherein the memory cell string selection switches that are turned on couple a plurality of channels of the selected memory strings with the corresponding bit lines respectively in the first phase.

3. The programming method according to claim 1, wherein the discharge voltage is less than or equal to 0 volts.

4. The programming method according to claim 1, wherein the inhibit voltage is greater than the select voltage.

5. The programming method according to claim 1, wherein the second phase and the third phase further comprise:
setting voltages of a plurality of source lines of the selected memory strings as a first voltage; and
setting voltages of a plurality of source lines of the de-selected memory strings as a second voltage,
wherein the second voltage is greater than the first voltage.

6. The programming method according to claim 1, further comprising:
providing a pass voltage to a plurality of word lines corresponding to a plurality of de-selected memory cells on the selected memory strings, wherein the pass voltage is less than the program voltage.

7. The programming method according to claim 1, further comprising:
turning off the memory cell string selection switches in the second phase and the third phase.

8. The programming method according to claim 1, wherein the first phase is a channel discharge phase, the second phase is a gate-induced-drain-leakage boost phase, and the third phase is a programming phase.

9. The programming method according to claim 1, wherein the first phase, the second phase, and the third phase occur sequentially.

10. A memory device, comprising:
a plurality of memory cell strings, divided into a plurality of selected memory strings and a plurality of de-selected memory strings in a programming operation; and
a controller, coupled to the memory cell strings, configured to:
respectively turn on a plurality of memory cell string selection switches of the selected memory string, apply a discharge voltage on a plurality of bit lines of the selected memory strings in a first phase;
apply a select voltage on the bit lines of the selected memory strings, apply an inhibit voltage on a plurality of bit lines of the de-selected memory strings in a second phase; and
provide a program voltage on a word line corresponding to a plurality of selected memory cells of the selected memory strings in a third phase.

11. The memory device according to claim 10, wherein the controller is further configured to:
the memory cell string selection switches that are turned on couple a plurality of channels of the selected memory strings with the corresponding bit lines respectively in the first phase.

12. The memory device according to claim 10, wherein the discharge voltage is less than or equal to 0 volts.

13. The memory device according to claim 10, wherein the inhibit voltage is greater than the select voltage.

14. The memory device according to claim 10, wherein the controller is further configured to:
set voltages of a plurality of source lines of the selected memory strings as a first voltage, set voltages of a plurality of source lines of the de-selected memory strings as a second voltage in the second phase and the third phase, wherein the second voltage is greater than the first voltage.

15. The memory device according to claim 10, wherein the controller is further configured to:
provide a pass voltage to a plurality of word lines corresponding to a plurality of de-selected memory cells on the selected memory strings, wherein the pass voltage is less than the program voltage.

16. The memory device according to claim 10, wherein the controller is further configured to:
turn off the memory cell string selection switches in the second phase and the third phase.

17. The memory device according to claim 10, wherein the controller is further configured to cause the first phase, the second phase, and the third phase to occur sequentially.
